(19) United States
(12) Patent Application Publication
(10) Pub. No.: US 2024/0118345 A1
(43) Pub. Date: Apr. 11, 2024

(54) BATTERY MANAGEMENT SYSTEM AND BATTERY MANAGEMENT METHOD

(71) Applicant: HONDA MOTOR CO., LTD., Tokyo (JP)

(72) Inventors: Tomoko Tamai, Tokyo (JP); Takashi Komaru, Tokyo (JP); Masanori Okabe, Tokyo (JP); Eiji Teramoto, Tokyo (JP); Kohei Fukunishi, Tokyo (JP)

(21) Appl. No.: 18/480,436

(22) Filed: Oct. 3, 2023

(30) Foreign Application Priority Data
Oct. 7, 2022 (JP) 2022-162535

(51) Int. Cl. G01R 31/3842; B60L 3/00; B60L 58/13; G01R 31/367; G01R 31/396

(52) U.S. Cl. CPC G01R 31/3842; B60L 3/0046; B60L 58/13; G01R 31/367; G01R 31/396

(57) ABSTRACT

A battery management system includes: a battery module accommodation section; a charging and discharging control section; and a shipping target selection section. The battery module accommodation section is configured to separately accommodate a plurality of battery modules in blocks. The blocks each includes a predetermined number of the battery modules. The predetermined number is greater than or equal to 2. The charging and discharging control section is configured to charge and discharge the battery modules in units of the blocks. The battery modules are accommodated in the battery module accommodation section. The shipping target selection section is configured to select, in units of the blocks, the battery modules serving as shipping targets from the battery modules accommodated in the battery module accommodation section.

### INCORPORATION BY REFERENCE

The present application claims priority under 35 U.S.C. § 119 to Japanese Patent Application No. 2022-162535 filed on Oct. 7, 2022. The content of the application is incorporated herein by reference in its entirety.

### BACKGROUND OF THE INVENTION

### Field of the Invention

The present invention relates to a battery management system and a battery management method.

### Description of the Related Art

In recent years, the reuse of secondary cells has been researched and developed to secure more people access to reasonable, reliable, sustainable, and advanced energy. The reuse of secondary cells contributes to an increase in the efficiency of energy. For example, Japanese Patent Nos. 6869580 and 6912125 each disclose a configuration in which, when used battery packs are stored, used battery packs to be discharged or charged are selected on the basis of the current values and the voltage values and the predetermined SOC (State Of Charge) ranges of the respective used battery packs and the used battery packs to be charged are supplied with charging power from the used battery packs to be discharged to cause the SOCs of the respective used battery packs to fall within predetermined ranges.

Incidentally, when used battery packs collected from electric vehicles or the like are reused and exploited, it is possible to conceive of not only a form in which the collected battery packs are shipped to a reuse destination as they are, but also a form in which the battery packs are disassembled and shipped in units of battery modules included in the battery packs. The present disclosure thus has an issue about such efficient storage and shipment in units of battery modules.

To solve the issue described above, an object of the present application is to provide a battery management system that supports the efficient storage and shipment of a plurality of battery modules. This eventually contributes to an improvement in the efficiency of energy.

### SUMMARY OF THE INVENTION

A first aspect for achieving the object described above includes a battery management system that manages storage and shipment of a plurality of battery modules. The battery management system includes: a battery module accommodation section; a charging and discharging control section; and a shipping target selection section. The battery module accommodation section is configured to separately accommodate a plurality of the battery modules in blocks. The blocks each include a predetermined number of the battery modules. The predetermined number is greater than or equal to 2. The charging and discharging control section is configured to charge and discharge the battery modules in units of the blocks. The battery modules are accommodated in the battery module accommodation section. The shipping target selection section is configured to select, in units of the blocks, the battery modules serving as shipping targets from the battery modules accommodated in the battery module accommodation section.

The battery management system described above may include a battery module state recognition section configured to recognize a state of each of the battery modules accommodated in the battery module accommodation section. The shipping target selection section may be configured to preferentially select, as a shipping target, the block including the battery module recognized by the battery module state recognition section as being in a predetermined defective state.

The battery management system described above may include: a spare battery module accommodation section configured to accommodate the predetermined number or a greater number of the battery modules each confirmed as being in a predetermined normal state; and a block exchange arrangement section configured to execute processing for exchanging the block including the battery module recognized by the battery module state recognition section as being in the defective state for the predetermined number of battery modules accommodated in the spare battery module accommodation section.

In the battery management system described above, the battery modules may be taken out from a battery pack collected from an electric vehicle. The battery management system described above may include: a battery pack information acquisition section configured to acquire battery pack information including information related to at least any one of a manufacture date of the electric vehicle equipped with the battery pack and a distance traveled by the electric vehicle equipped with the battery pack; and a spare battery module selection section configured to select, on the basis of the battery pack information, the battery module that is accommodated in the spare battery module accommodation section from the battery modules taken out from the battery pack.

A second aspect for achieving the object described above includes a battery management method that is executed by a computer to manage storage and shipment of a plurality of battery modules. The battery management method includes: a battery module registration step; a charging and discharging control step; and a shipping target selection step. In the battery module registration step, a plurality of the battery modules is separately registered in blocks. The plurality of the battery modules is accommodated in a battery module accommodation section. The blocks each includes a predetermined number of the battery modules. The predetermined number being greater than or equal to 2. In the charging and discharging control step, the battery modules are charged and discharged in units of the blocks. The battery modules are accommodated in the battery module accommodation section. In the shipping target selection step, the battery modules serving as shipping targets are selected in units of the blocks from the battery modules accommodated in the battery module accommodation section.

The battery management system described above makes it possible to support efficient storage and shipment of a plurality of battery modules.

### BRIEF DESCRIPTION OF THE DRAWINGS

FIG. 1 is an explanatory diagram of a battery reuse mode in which a battery management system is used;

FIG. 2 is a configuration diagram of the battery management system;

FIG. 3 is an explanatory diagram of registration data of a battery module;

FIG. 4 is a flowchart of processing of selecting the battery module; and

FIG. 5 is a flowchart of processing of exchanging the battery modules.

### DETAILED DESCRIPTION OF THE PREFERRED EMBODIMENTS

### 1. Battery Reuse Mode

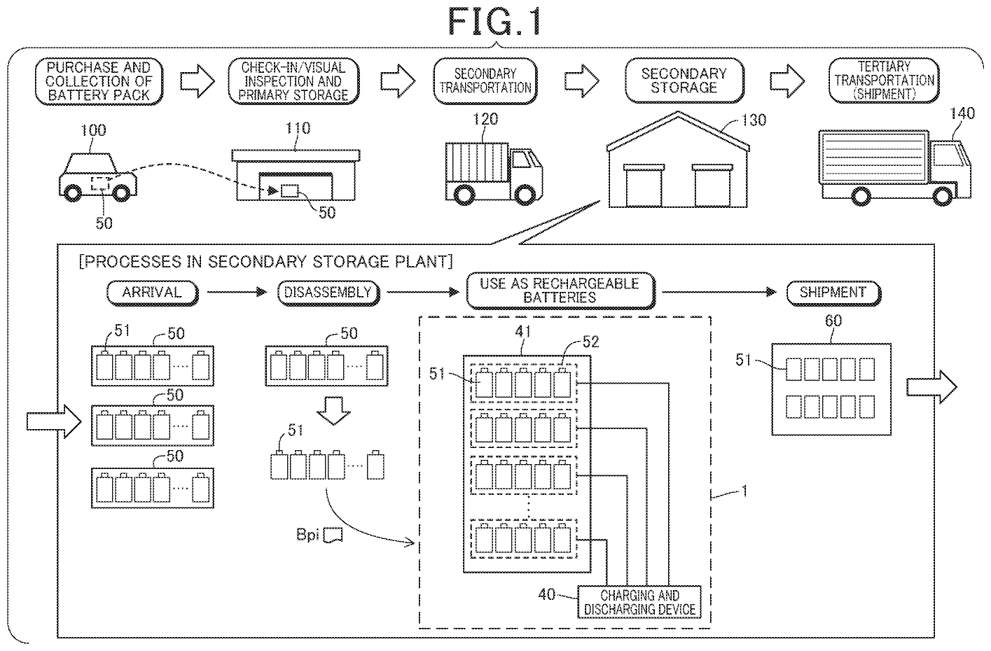

A battery reuse mode to which a battery management system 1 according to the present disclosure is applied will be described with reference to FIG. 1. In the present embodiment, an example is described in which a battery pack 50 mounted in an electric vehicle 100 is collected and battery modules 51 taken out from the disassembled battery pack 50 are stored and then shipped.

The electric vehicle 100 is a vehicle such as a BEV (Battery Electric Vehicle), an HEV (Hybrid Electric Vehicle), or a PHEV (Plug-in Hybrid Electric Vehicle) including a battery as a power source. The battery pack 50 includes the plurality of battery modules 51 connected in series or in parallel. The battery modules 51 each include a plurality of connected cells and serve as the smallest element when the battery is reused. Each of the cells is a single encapsulated unit including one positive electrode, one negative electrode, and an electrolyte solution.

The battery pack 50 collected from the electric vehicle 100 is transported (primary transportation) to a primary storage plant 110, checks in and undergoes a visual inspection, and then stored in the primary storage plant 110. The battery packs 50 stored in the primary storage plant 110 are sequentially transported (secondary transportation) to a secondary storage plant 130 by a transport vehicle 120.

In the secondary storage plant 130, the battery packs 50 that arrive through transportation by the transport vehicle 120 are disassembled by an operator or a robot and the battery modules 51 are taken out. In addition, battery pack information Bpi stored in a memory of each of the battery packs 50 is transferred to the battery management system 1. The battery pack information Bpi is transferred by connecting the battery pack 50 and the battery management system 1 and performing communication. Alternatively, the battery pack information Bpi is transferred by an operator operating a terminal device connected to the battery management system 1, for example, to input the battery pack information Bpi read out from the battery pack 50.

In addition, when the battery pack information Bpi is not recorded in the memory of the battery pack 50, a battery data server that communicates with the electric vehicle 100 and the battery management system 1 transfers, to the battery management system 1, the battery pack information Bpi of the battery pack 50 collected from the electric vehicle 100. The battery data server stores the battery pack information Bpi transmitted from the electric vehicle 100 in association with pieces of identification information of the electric vehicle 100 and the battery pack 50. The identification information of the battery pack 50 is referenced to transfer the battery pack information Bpi from the battery data server to the battery management system 1.

The battery pack information Bpi includes pieces of information related to the manufacture date of the electric vehicle 100 equipped with the battery pack 50 and the total distance traveled by the electric vehicle 100 equipped with the battery pack 50. It is possible to recognize the use period of the battery pack 50 from the manufacture date of the electric vehicle 100 and recognize the use condition of the battery pack 50 from the total distance traveled by the electric vehicle 100. It is to be noted that any one of the manufacture date of the electric vehicle 100 and the total distance traveled by the electric vehicle 100 alone may be included in the battery pack information Bpi or information (such as a use environment in which the electric vehicle 100 used to be) other than the manufacture date and the total traveled distance may be included in the battery pack information Bpi.

The battery management system 1 accommodates the plurality of battery modules 51 in a battery module accommodation section 41 in units of blocks 52 and manages the plurality of battery modules 51 in units of blocks 52. In the present embodiment, an example is described in which the five battery modules 51 are managed as the one block 52, but the number of battery modules 51 included in the block 52 may be less than 5 (corresponding to a predetermined number in the present disclosure) or greater than 5. Although described in detail below, the battery management system 1 stores the battery modules 51 accommodated in the battery module accommodation section 41 while charging and discharging the battery modules 51 by a charging and discharging device 40 in units of blocks 52.

In addition, the battery management system 1 makes defect determinations for the battery modules 51 accommodated in the battery module accommodation section 41. The battery management system 1 selects, as a shipping target, the battery module 51 determined as a non-defective product. The battery management system 1 selects, as a discarding target, the battery module 51 determined as a defective product. The battery management system 1 makes arrangements to ship the battery module 51 selected as a shipping target.

When a shipping operation is performed by a robot, the battery management system 1 makes arrangements for shipment by transmitting, to the robot, shipment instruction information including the identification information of the battery module 51 that is a shipping target. In addition, when a shipping operation is performed by an operator, the battery management system 1 makes arrangements for shipment by transmitting, to a terminal device (such as a personal computer or a tablet terminal) used by the operator, the shipment instruction information including the identification information of the battery module 51 that is a shipping target. A package 60 in which the battery modules 51 are packed is shipped from the secondary storage plant 130 through the shipping operation and delivered to a delivery destination by a transport vehicle 140.

### 2. Configuration of Battery Management System

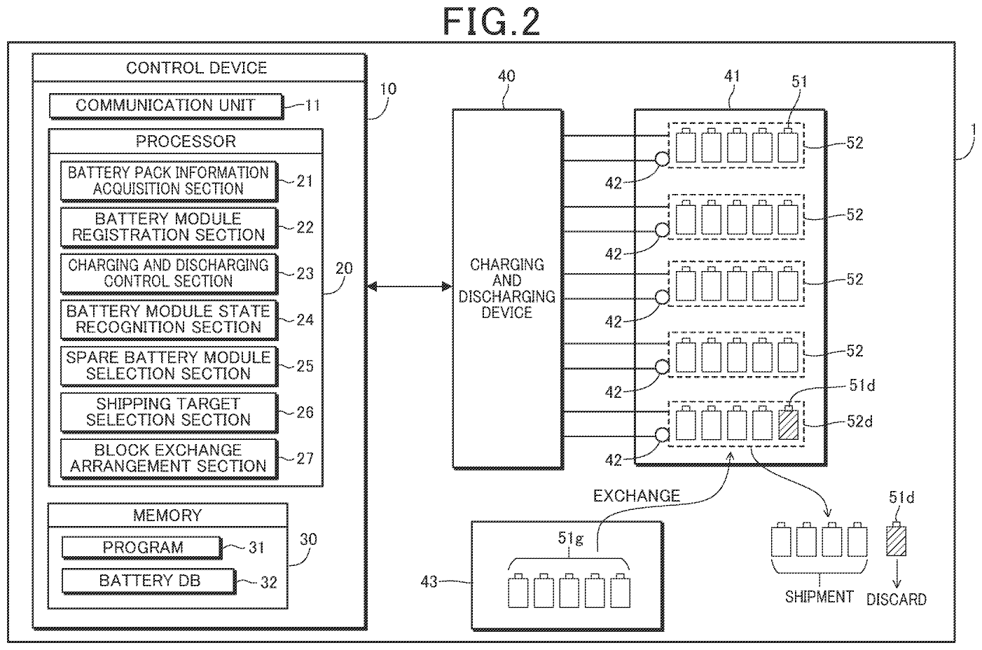

A configuration of the battery management system 1 will be described with reference to FIG. 2. The battery management system 1 includes a control device 10, the charging and discharging device 40, the battery module accommodation section 41, and a spare battery module accommodation section 43.

The battery module accommodation section 41 separately accommodates the plurality of battery modules 51 in a predetermined number (the present embodiment exemplifies 5) of blocks 52. Each of the blocks 52 is provided with a battery sensor 42 that individually detects the states (such as the voltage, the current, and the temperature) of the accommodated battery modules 51.

The charging and discharging device 40 is connected to the battery module accommodation section 41. The charging and discharging device 40 supplies each of the battery modules 51 accommodated in the battery module accommodation section 41 with power to charge the battery module 51. In addition, the charging and discharging device 40 collects power output from each of the battery modules 51 to discharge the battery module 51. The charging and discharging device 40 receives a signal of detection by each of the battery sensors 42.

The charging and discharging device 40 communicates with the control device 10 and charges and discharges the battery modules 51 accommodated in the battery module accommodation section 41 in units of blocks 52 on the basis of control information transmitted from the control device 10. In addition, the charging and discharging device 40 transmits information related to the detection by the battery sensor 42 to the control device 10. The spare battery module accommodation section 43 accommodates battery modules 51g each confirmed as a non-defective product.

The control device 10 is a computer device including a communication unit 11, a processor 20, a memory 30, and the like. The communication unit 11 communicates with the charging and discharging device 40, a working robot that operates in the secondary storage plant 130, a management device for the working robot, a terminal device that is disposed in the secondary storage plant 130 and used by an operator, and the like.

The memory 30 stores a program 31 for the control device 10 and a battery DB (database) 32 in which the battery pack information Bpi and information related to each of the battery modules 51 accommodated in the battery module accommodation section 41 or the spare battery module accommodation section 43 are recorded. The processor 20 reads and executes the program 31 to function as a battery pack information acquisition section 21, a battery module registration section 22, a charging and discharging control section 23, a battery module state recognition section 24, a spare battery module selection section 25, a shipping target selection section 26, and a block exchange arrangement section 27.

Processing that is executed by the battery module registration section 22 corresponds to a battery module registration step in a battery management method according to the present disclosure. Processing that is executed by the charging and discharging control section 23 corresponds to a charging and discharging control step in the battery management method according to the present disclosure. Processing that is executed by the shipping target selection section 26 corresponds to a shipping target selection step in the battery management method according to the present disclosure.

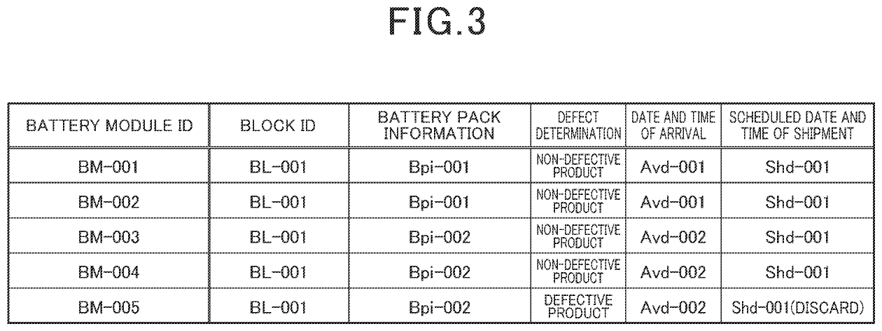

As described above with reference to FIG. 1, the battery pack information acquisition section 21 acquires, through the communication unit 11, the battery pack information Bpi acquired on the arrival of the battery pack 50. The battery pack information acquisition section 21 records the battery pack information Bpi in the battery DB 32. As illustrated in FIG. 3, the battery module registration section 22 sets IDs (identifications) for the incoming battery modules 51 and separately registers the IDs in units of blocks 52.

FIG. 3 illustrates an example in which the five battery modules 51 for which BM-001 to BM-005 are set as battery module IDs are registered in the block 52 for which BL-001 is set as a block ID. The two battery modules 51 for which BM-001 and BM-002 are set as battery module IDs are taken out from the same battery pack 50 and common battery pack information Bpi-001 is thus recorded.

In addition, the three battery modules 51 for which BM-003 to BM-005 are set as battery module IDs are taken out from the same battery pack 50 and common battery pack information Bpi-002 is thus recorded. Pieces of information related to a result of a determination about a non-defective product or a defective product made on the basis of a result of recognition by the battery module state recognition section 24 described below, the date and time of arrival at the secondary storage plant 130, and the scheduled date and time of shipment from the secondary storage plant 130 are recorded for each of the battery modules 51 in association with the battery module ID.

The charging and discharging control section 23 controls the charging and discharging of the battery modules 51 accommodated in the battery module accommodation section 41 by the charging and discharging device 40 in units of blocks 52. The charging and discharging control section 23 charges and discharges each of the battery modules 51 accommodated in the battery module accommodation section 41 to keep the charge level of the battery module 51 within a predetermined range.

The battery module state recognition section 24 recognizes whether each of the battery modules 51 accommodated in the battery module accommodation section 41 is a non-defective product or a defective product on the basis of the information related to the detection by the battery sensor 42 such as the voltage, the current, and the temperature and the charge upper limit level of the battery module 51. For example, the battery module state recognition section 24 recognizes the battery module 51 as a non-defective product when the full-charge amount of the battery module 51 that is a recognition target is 80% or more of a prescribed charge amount and recognizes the battery module 51 as a defective product when the full-charge amount is less than 80% of the prescribed charge amount.

The spare battery module selection section 25 recognizes the manufacture dates of the electric vehicles 100 equipped with the battery packs 50 and the total distances traveled by the electric vehicles 100 equipped with the battery packs 50 from the pieces of battery pack information Bpi. The spare battery module selection section 25 extracts the battery pack 50 of the electric vehicle 100 that has a shorter elapsed period from the manufacture date than a predetermined period, has traveled a predetermined distance or less in total, and is estimated to have imposed a light usage load on the battery pack 50. The spare battery module selection section 25 then selects the battery modules 51 taken out from the extracted battery pack 50 as the battery modules 51g that are accommodated in the spare battery module accommodation section 43.

The shipping target selection section 26 selects the battery modules 51 serving as shipping targets in units of blocks 52 from the battery modules 51 accommodated in the battery module accommodation section 41. The shipping target selection section 26 preferentially selects, as a shipping target, the block 52 including the battery module 51 recognized as a defective product by the battery module state recognition section 24. FIG. 2 exemplifies a case where a block 52d including a battery module 51d recognized as a defective product is preferentially selected as a shipping target by the shipping target selection section 26.

When the block 52d including the battery module 51d recognized as a defective product is selected as a shipping target, the block exchange arrangement section 27 makes arrangements to perform processing of exchanging the battery modules 51 included in the block 52d for the battery modules 51 accommodated in the spare battery module accommodation section 43. In the example of FIG. 2, all the battery modules 51 of the block 52d including the battery module 51d recognized as a defective product are exchanged for the non-defective battery modules 51g accommodated in the spare battery module accommodation section 43.

The defective battery module 51d included in the block 52d is discarded and the other non-defective battery modules 51 serve as shipping targets. When an exchanging operation is performed by a robot, the block exchange arrangement section 27 exchanges the battery modules 51 in units of blocks 52 by transmitting exchange instruction information including the ID of the block 52d serving as an exchange target from the battery management system 1 to the robot. In addition, when an exchanging operation is performed by an operator, the block exchange arrangement section 27 exchanges the battery modules 51 in units of blocks 52 by the battery management system 1 transmitting, to a terminal device (such as a personal computer or a tablet terminal) used by the operator, the exchange instruction information including the ID of the block 52d that is an exchange target.

### 3. Processing of Selecting Battery Module

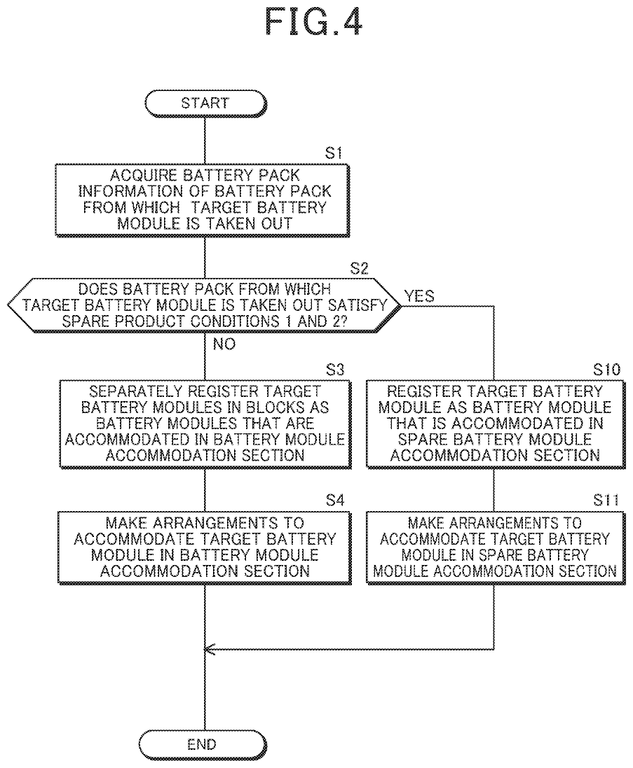

Processing of selecting the incoming battery module 51 will be described in accordance with the flowchart illustrated in FIG. 4. The processing is executed by the battery management system 1. The battery management system 1 executes the processing of the flowchart illustrated in FIG. 4 for each of the battery modules 51 taken out from the battery pack 50. The following gives a description by referring to the battery module 51 to be processed as a target battery module 51.

In step 1 of FIG. 4, the battery pack information acquisition section 21 acquires the battery pack information Bpi of the battery pack 50 from which the target battery module 51 is taken out. In subsequent step S2, the spare battery module selection section 25 determines, on the basis of the battery pack information Bpi, whether or not the battery pack 50 from which the target battery module 51 is taken out satisfies both of the following spare product conditions 1 and 2.

Spare product condition 1: the elapsed period from the manufacture date of the electric vehicle 100 equipped with the battery pack 50 is less than or equal to a predetermined period.

Spare product condition 2: the total distance traveled by the electric vehicle 100 equipped with the battery pack 50 is less than or equal to a predetermined distance.

It is to be noted that any one of the spare product condition 1 and the spare product condition 2 alone may be determined.

The battery module registration section 22 brings the processing to step S10 when the battery pack 50 satisfies both of the spare product conditions 1 and 2 and brings the processing to step S3 when the battery pack 50 does not satisfy at least any one of the spare product conditions 1 and 2. In step S3, the battery module registration section 22 assigns the target battery module 51 to the block 52 as the battery module 51 that is accommodated in the battery module accommodation section 41 and records and registers the target battery module 51 in the battery DB 32 as described above with reference to FIG. 3.

In next step S4, the battery module registration section 22 executes processing of making arrangements to accommodate the target battery module 51 in the battery module accommodation section 41. This processing is performed by the battery module registration section 22 transmitting instruction information to a working robot or a terminal device used by an operator. The instruction information is for instructing the battery module accommodation section 41 to accommodate the target battery module 51.

In addition, in step S10, the spare battery module selection section 25 records and registers the target battery module 51 to the battery DB 32 as the battery module 51 that is accommodated in the spare battery module accommodation section 43. In next step S11, the spare battery module selection section 25 makes arrangements to accommodate the target battery module 51 in the spare battery module accommodation section 43. These arrangements are made by the spare battery module selection section 25 transmitting instruction information to a working robot or a terminal device used by an operator. The instruction information is for instructing the spare battery module accommodation section 43 to accommodate the target battery module 51.

### 4. Processing of Making Defect Determination for Battery Module

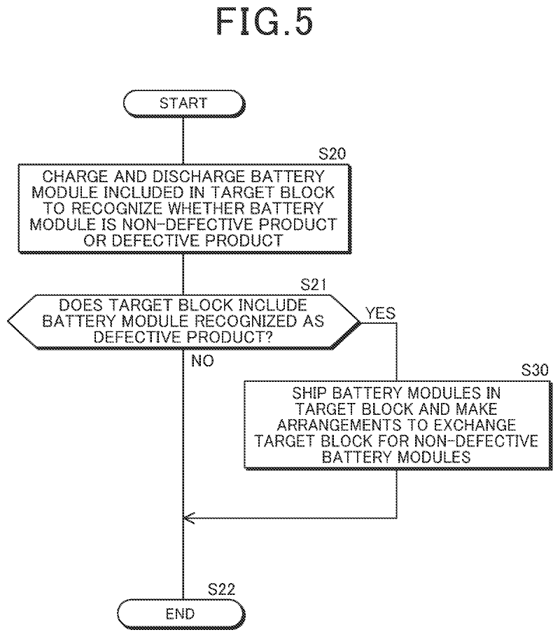

Processing of making defect determinations for the battery modules 51 accommodated in the battery module accommodation section 41 for each of the blocks 52 will be described in accordance with the flowchart illustrated in FIG. 5. Processing of the flowchart illustrated in FIG. 5 is executed for each of the blocks 52. The following gives a description by referring to the block 52 to be processed as a target block 52.

In step S20, the battery module state recognition section 24 determines whether each of the battery modules 51 belonging to the target block 52 is a non-defective product or a defective product by charging and discharging the battery module 51 by the charging and discharging control section 23. The execution of charging and discharging control for a predetermined period in units of target blocks 52 makes it possible to recognize whether the target blocks 52 each include a defective battery module and further use makes it possible to recognize which is the defective battery module in the target block 52. Charging and discharging control and shipping target selection in units of blocks therefore allow for an efficient operation. The battery module state recognition section 24 recognizes the battery module 51 as a non-defective product when the full-charge amount of the battery module 51 is 80% or more of the prescribed charge amount and recognizes the battery module 51 as a defective product when the full-charge amount is less than 80% of the prescribed charge amount.

In subsequent step S21, the shipping target selection section 26 brings the processing to step S30 when the target block 52 includes the target battery module 51 recognized as a defective product and brings the processing to step S22 when the target block 52 does not include the target battery module 51 recognized as a defective product. In step S30, the shipping target selection section 26 selects the non-defective battery modules 51 included in the target block 52 as shipping targets and selects the defective battery module 51 (the battery module 51d in the example of FIG. 2) included in the target block 52 as a discarding target.

The shipping target selection section 26 then executes processing of making arrangements to ship the selected non-defective battery modules 51 and discard the selected defective battery module 51. In addition, the block exchange arrangement section 27 executes processing of making arrangements to exchange the battery modules 51 that serve as shipping or discarding targets and are included in the target block 52 for the non-defective battery modules 51g accommodated in the spare battery module accommodation section 43.

The processing of making these arrangements is performed by the shipping target selection section 26 and the block exchange arrangement section 27 transmitting pieces of instruction information to a working robot or a terminal device used by an operator. The pieces of instruction information are for issuing instructions to make these arrangements.

### 5. Other Embodiments

In the embodiment described above, as illustrated in FIG. 2, the spare battery module accommodation section 43 is included and makes arrangements to exchange the non-defective battery modules 51g included in the spare battery module accommodation section 43 for the block 52d including the defective battery module 51d. As another embodiment, a configuration may be adopted in which the spare battery module accommodation section 43 and the block exchange arrangement section 27 are omitted.

In the embodiment described above, as illustrated in FIG. 2, the shipping target selection section 26 preferentially selects the block 52d including the defective battery module 51d as a shipping target, but a configuration may be adopted in which such a preferential selection is not made.

In the embodiment described above, as illustrated in FIG. 2, the battery pack information acquisition section 21 is included and the spare battery module selection section 25 selects the non-defective battery modules 51g that are accommodated in the spare battery module accommodation section 43 on the basis of the battery pack information Bpi. As another embodiment, the battery modules 51 that are accommodated in the spare battery module accommodation section 43 may be selected on the basis of a result of recognition by the battery module state recognition section 24 without using the battery pack information Bpi. Alternatively, the battery modules 51 that are accommodated in the spare battery module accommodation section 43 may be selected on the basis of both the battery pack information Bpi and the result of the recognition by the battery module state recognition section 24.

It is to be noted that FIG. 2 is a schematic diagram in which the configuration of the battery management system 1 is divided in accordance with the chief processing contents for facilitating the understandings of the invention according to the present application. The battery management system 1 may be configured in accordance with other division. In addition, the processing of each of the components may be executed by one hardware unit or executed by a plurality of hardware units. In addition, the processing by each of the components illustrated in any of FIGS. 4 and 5 may be executed by one program or executed by a plurality of programs.

### 6. Configurations Supported by Embodiments Above

The embodiments described above are specific examples of the following configurations.

(Configuration 1) A battery management system that manages storage and shipment of a plurality of battery modules, the battery management system including: a battery module accommodation section configured to separately accommodate a plurality of the battery modules in blocks, the blocks each including a predetermined number of the battery modules, the predetermined number being greater than or equal to 2; a charging and discharging control section configured to charge and discharge the battery modules in units of the blocks, the battery modules being accommodated in the battery module accommodation section; and a shipping target selection section configured to select, in units of the blocks, the battery modules serving as shipping targets from the battery modules accommodated in the battery module accommodation section.

The battery management system according to Configuration 1 makes it possible to support efficient storage and shipment of the plurality of battery modules.

(Configuration 2) The battery management system according to Configuration 1, including a battery module state recognition section configured to recognize a state of each of the battery modules accommodated in the battery module accommodation section, in which the shipping target selection section preferentially selects, as a shipping target, the block including the battery module recognized by the battery module state recognition section as being in a predetermined defective state.

The battery management system according to Configuration 2 preferentially selects the block including the battery module in the defective state as the shipping target to make it possible to quickly eject the battery in the defective state from the battery module accommodation section and ship the remaining battery modules of the block without keeping the remaining battery modules in the battery module accommodation section.

(Configuration 3) The battery management system according to Configuration 2, including: a spare battery module accommodation section configured to accommodate the predetermined number or a greater number of the battery modules each confirmed as being in a predetermined normal state; and a block exchange arrangement section configured to execute processing for exchanging the block including the battery module recognized by the battery module state recognition section as being in the defective state for the predetermined number of battery modules accommodated in the spare battery module accommodation section.

The battery management system according to Configuration 3 exchanges the block including the battery module in the defective state for the battery modules each in the normal state in units of blocks to make it possible to quickly eject the battery module in the defective state from the battery module accommodation section and use the battery module accommodation section more effectively. The battery modules each in the normal state is prepared in advance.

(Configuration 4) The battery management system according to Configuration 3, in which the battery modules are taken out from a battery pack collected from an electric vehicle, and the battery management system includes: a battery pack information acquisition section configured to acquire battery pack information including information related to at least any one of a manufacture date of the electric vehicle equipped with the battery pack and a distance traveled by the electric vehicle equipped with the battery pack; and a spare battery module selection section configured to select, on the basis of the battery pack information, the battery module that is accommodated in the spare battery module accommodation section from the battery modules taken out from the battery pack.

The battery management system according to Configuration 4 makes it possible to select, on the basis of the battery pack information, a battery module estimated to be in a favorable state under the condition that the use period is short or the vehicle equipped with the battery pack has traveled a short distance and accommodate the battery module in the spare battery module accommodation section.

(Configuration 5) A battery management method that is executed by a computer to manage storage and shipment of a plurality of battery modules, the battery management method including: a battery module registration step of separately registering a plurality of the battery modules in blocks, the plurality of the battery modules being accommodated in a battery module accommodation section, the blocks each including a predetermined number of the battery modules, the predetermined number being greater than or equal to 2; a charging and discharging control step of charging and discharging the battery modules in units of the blocks, the battery modules being accommodated in the battery module accommodation section; and a shipping target selection step of selecting, in units of the blocks, the battery modules serving as shipping targets from the battery modules accommodated in the battery module accommodation section.

The battery management method according to Configuration 5 is executed by a computer to make it possible to register the plurality of battery modules in units of blocks, store the battery modules while efficiently charging and discharging the battery modules in units of blocks, and efficiently select battery modules serving as shipping targets in units of blocks.

### REFERENCE SIGNS LIST

1 battery management system
10 control device
11 communication unit
20 processor
21 battery pack information acquisition section
22 battery module registration section
23 charging and discharging control section
24 battery module state recognition section
25 spare battery module selection section
26 shipping target selection section
27 block exchange arrangement section
30 memory
31 program
32 battery DB
40 charging and discharging device
41 battery module accommodation section
42 battery sensor
43 spare battery module accommodation section
50 battery pack
51 battery module
52 block
51d defective battery module
51g non-defective battery module
60 package
100 electric vehicle
110 primary storage plant
120 transport vehicle
130 secondary storage plant
140 transport vehicle

What is claimed is:

1. A battery management system that manages storage and shipment of a plurality of battery modules, the battery management system comprising:
a battery module accommodation section configured to separately accommodate a plurality of the battery modules in blocks, the blocks each including a predetermined number of the battery modules, the predetermined number being greater than or equal to 2;
a charging and discharging control section configured to charge and discharge the battery modules in units of the blocks, the battery modules being accommodated in the battery module accommodation section; and
a shipping target selection section configured to select, in units of the blocks, the battery modules serving as shipping targets from the battery modules accommodated in the battery module accommodation section.

2. The battery management system according to claim 1, comprising a battery module state recognition section configured to recognize a state of each of the battery modules accommodated in the battery module accommodation section, wherein
the shipping target selection section preferentially selects, as a shipping target, the block including the battery module recognized by the battery module state recognition section as being in a predetermined defective state.

3. The battery management system according to claim 2, comprising:
a spare battery module accommodation section configured to accommodate the predetermined number or a greater number of the battery modules each confirmed as being in a predetermined normal state; and
a block exchange arrangement section configured to execute processing for exchanging the block including the battery module recognized by the battery module state recognition section as being in the defective state for the predetermined number of battery modules accommodated in the spare battery module accommodation section.

4. The battery management system according to claim 3, wherein
the battery modules are taken out from a battery pack collected from an electric vehicle, and
the battery management system comprises:
a battery pack information acquisition section configured to acquire battery pack information including information related to at least any one of a manufacture date of the electric vehicle equipped with the battery pack and a distance traveled by the electric vehicle equipped with the battery pack; and
a spare battery module selection section configured to select, on a basis of the battery pack information, the battery module that is accommodated in the spare battery module accommodation section from the battery modules taken out from the battery pack.

5. A battery management method that is executed by a computer to manage storage and shipment of a plurality of battery modules, the battery management method comprising:
a battery module registration step of separately registering a plurality of the battery modules in blocks, the plurality of the battery modules being accommodated in a battery module accommodation section, the blocks each including a predetermined number of the battery modules, the predetermined number being greater than or equal to 2;
a charging and discharging control step of charging and discharging the battery modules in units of the blocks, the battery modules being accommodated in the battery module accommodation section; and
a shipping target selection step of selecting, in units of the blocks, the battery modules serving as shipping targets from the battery modules accommodated in the battery module accommodation section.
